(19) United States
(12) Patent Application Publication
(10) Pub. No.: US 2012/0169368 A1
(43) Pub. Date: Jul. 5, 2012

(54) TEST CIRCUIT OF SOURCE DRIVER

(75) Inventors: Ji-Ting Chen, Hsinchu County (TW); Shun-Hsun Yang, Hsinchu City (TW); Kuang-Feng Sung, Taichung City (TW)

(73) Assignee: NOVATEK MICROELECTRONICS CORP., Hsinchu (TW)

(21) Appl. No.: 13/191,488

(22) Filed: Jul. 27, 2011

(30) Foreign Application Priority Data
Jan. 3, 2011 (TW) 100100063

(51) Int. Cl. G01R 31/40

(52) U.S. Cl. 324/764.01

(57) ABSTRACT

A test circuit of a source driver is disclosed. The test circuit includes a voltage selector and at least one digital-to-analog converter (DAC). The voltage selector has a plurality of first output terminals. The voltage selector outputs a first voltage at one of the first output terminals in a sequential order according to a selection signal and outputs a second voltage at the other first output terminals. Each of the at least one DACs has a plurality of the input terminals respectively coupled to the first output terminals and also has a second output terminal. The DAC transmits the first voltage received by one of the input terminals to the second output terminal in a sequential order according to the selection signal.

### CROSS-REFERENCE TO RELATED APPLICATION

This application claims the priority benefit of Taiwan application serial no. 100100063, filed Jan. 3, 2011. The entirety of the above-mentioned patent application is hereby incorporated by reference herein and made a part of this specification.

### BACKGROUND OF THE INVENTION

1. Field of Invention

The invention relates generally to a testing technique of a source driver, and more particularly to a high speed test circuit of a source driver.

2. Description of Related Art

Referring to FIG. 1, a schematic diagram of a conventional source driver 100 is shown. The source driver 100 for driving a display apparatus includes a gamma voltage generator 110 to provide a plurality of gamma voltages. The gamma voltages are provided to the digital-to-analog converters (DACs) 120 and 130. The DACs 120 and 130 respectively receive the data signals DATA1 and DATA2 and select one of the plurality of gamma voltages provided by the gamma voltage generator 110 to output in accordance with the data signals DATA1 and DATA2.

Under the conventional framework of the source driver 100, when the accuracy of the gamma voltage selected by the DACs 120 and 130 needs to be determined, the voltages on the bonding pads OPAD1 and OPAD2 are measured under the condition that the switches SW1 and SW2 are turned on. Since the DACs 120 and 130 receive the multi-bit data signals DATA1 and DATA2, the selectable output gamma voltages thereof have a plurality of different possible voltage values. Using the DAC 120 receiving the 8-bit data signal DATA1 as an example, the DAC 120 needs to provide gamma voltages of 256 different voltage levels. Accordingly, when testing each one of the possible gamma voltages the DAC 120 may provide, a lengthy testing period is clearly necessary.

Moreover, the voltages on the bonding pads OPAD1 and OPAD2 are outputted through the operational amplifiers OP1 and OP2. However, the operational amplifiers OP1 and OP2 require a long wait time in order to provide each stable gamma voltage to the bonding pads OPAD1 and OPAD2 for testing. As a result, a complete test of all the gamma voltages with different voltage levels requires an enormous time investment, which adds to the testing costs.

### SUMMARY OF THE INVENTION

Accordingly, the invention is directed to providing test circuits for a source driver capable of effectively enhancing a testing speed.

An embodiment of the invention provides a test circuit of a source driver, including a voltage selector and at least one digital-to-analog converter (DAC). The voltage selector has a plurality of first output terminals. The voltage selector is configured to transmit a first voltage at one of the first output terminals in a sequential order according to a selection signal, and output a second voltage at the other first output terminals. Each of the DACs has a plurality of input terminals respectively coupled to the first output terminal, and a second output terminal. The DACs are configured to transmit the first voltage received by one of the input terminals to the second output terminal in a sequential order according to the selection signal.

An embodiment of the invention provides another test circuit of a source driver, including a test input current source and a first DAC. The test input current source outputs a test input current at a first output terminal according to a test activating signal. The first DAC has a plurality of first input terminals coupled to the first output terminal, and a second output terminal. The first DAC is configured to transmit the test input current received by one of the first input terminals to the second output terminal in a sequential order according to the selection signal, to serve as an output current indicating a test result.

An embodiment of the invention provides another test circuit of a source driver, including a gamma voltage generator, at least one operational amplifier, at least one output switch, and at least one test auxiliary circuit. The gamma voltage generator is configured to generate a plurality of gamma voltages. Each of the DACs has a plurality of input terminals receiving one of the gamma voltages, and a second output terminal, configured to transmit the gamma voltage received by one of the input terminals to the second output terminal in a sequential order according to the selection signal, to serve as an output voltage. Each of the operational amplifiers is coupled to the second terminal of the corresponding DAC. Each of the output switches is serially coupled between an output terminal of the corresponding operational amplifier and a corresponding one of at least one test terminals, the at least one output switches turning on or off according to a test activating signal. Each of the at least one test auxiliary circuits is coupled between the second output terminal of the corresponding DAC and the corresponding test terminal, configured to transmit the output voltage at the second output terminal of the corresponding DAC to the test terminal when the test activating signal is enabled.

An embodiment of the invention provides another test circuit of a source driver, including an operational amplifier and a DAC. The operational amplifier has an input terminal, the DAC has a plurality of input terminals coupled to one or more test input signals, and the DAC has an output terminal coupled to the input terminal of the operational amplifier. The DAC is configured to transmit the test signal received by one of the input terminals to the output terminal in a sequential order according to the selection signal, to serve as a test output signal. Moreover, the test output signal is outputted from the test circuit through a test path to indicate a test result, in which the test path does not pass through the operational amplifier.

In summary, according to embodiments of the invention, the DACs in the source driver can be tested without relying directly on the operational amplifiers of the digital circuits during the test procedure. Therefore, when testing the DACs, it is no longer required to wait for the lengthy stabilizing time of the operational amplifiers. Consequently, the testing speed can be drastically increased and the testing costs can be effectively lowered.

In order to make the aforementioned and other objects, features and advantages of the disclosure comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a conventional source driver.

FIG. 2 is a schematic diagram of a test circuit of a source driver according to an embodiment of the invention.

FIG. 3A is a schematic diagram of an implementation of the voltage selector depicted in FIG. 2 according to an embodiment of the invention.

FIG. 3B is a waveform diagram of the selection signal in FIG. 2 according to an embodiment of the invention.

FIG. 4 is a partial circuit diagram of the DAC depicted in FIG. 2 according to an embodiment of the invention.

FIG. 5 is an operational waveform diagram of the DAC depicted in FIG. 4 according to an embodiment of the invention.

FIG. 6 is a schematic diagram of a test circuit of a source driver according to another embodiment of the invention.

FIG. 7 is a partial circuit diagram of the DAC depicted in FIG. 6 according to an embodiment of the invention.

FIG. 8 is a schematic diagram of a test circuit of a source driver according to another embodiment of the invention.

FIG. 9A is a schematic diagram of a test circuit of a source driver according to another embodiment of the invention.

FIG. 9B is a schematic diagram of a test auxiliary circuit depicted in FIG. 9A according to an embodiment of the invention.

### DESCRIPTION OF EMBODIMENTS

Referring to FIG. 2, a schematic diagram of a test circuit 200 of a source driver according to an embodiment of the invention is shown. The test circuit 200 of the source driver includes a voltage selector 210 and the digital-to-analog converters (DACs) 220 and 230. The voltage selector 210 receives a first voltage VA1, a second voltage VA2, and a selection signal SEL. The voltage selector 210 has a plurality of output terminals (not drawn), and the voltage selector 210 is configured to output the first voltage VA1 at one of the first output terminals in a sequential order according to the selection signal SEL, and outputting the second voltage VA2 at the other first output terminals which did not output the first voltage VA1.

More specifically, in a case where the DACs 220 and 230 are M-bit DACs (M being a positive integer), the voltage selector 210 can have M output terminals. Additionally, in a first time period, the voltage selector 210 outputs the first voltage VA1 at a first output terminal according to the selection signal SEL, and outputs the second voltage VA2 at the other output terminals. Thereafter, in a second time period, the voltage selector 210 outputs the first voltage VA1 at a second output terminal according to the modified selection signal SEL, and outputs the second voltage VA2 at the other output terminals. In the same manner, the voltage selector 210 changes the output terminal outputting first voltage VA1 in a sequential order according to the continuously varying selection signal SEL, until all of the output terminals have outputted the first voltage VA1.

Regarding the DACs 220 and 230, using the DAC 220 as an example, the DAC 220 has a plurality of input terminals and an output terminal, and a plurality of channels are formed between the input terminals and the output terminal. The plurality of input terminals of the DAC 220 are respectively coupled to the corresponding output terminal of the voltage selector 210, in order to receive a first voltage VA1 and a plurality of second voltages VA2 provided by the voltage selector 210. Moreover, the channels in the DAC 220 are turned on or off according to the selection signal SEL, so the output terminal selected by the voltage selector 210 to output the first voltage VA1 is coupled to the output terminal of the DAC 220.

In other words, during a testing process the selection signal SEL is configured to vary continually so the voltage selector 210 changes the output terminal outputting the first voltage VA1 in a sequential order. At the same time, the DAC 220 also receives the selection signal SEL to synchronously switch the conductive states of the plurality of channels in the DAC 220. Accordingly, the output terminal selected by the voltage selector 210 outputting the first voltage VA1 may be coupled to the output terminal of the DAC 220 through the conducting channels. If all of the channels are not damaged, the output terminal of the DAC 220 can output the first voltage VA1 in a stable manner. Conversely, if any one of the channels is damaged, the output terminal of the DAC 220 cannot output the first voltage VA1 in a stable manner.

Moreover, the test circuit 200 of the source driver further includes the operational amplifiers OP1 and OP2 and the output switches OSW1 and OSW2. The operational amplifier OP1 and the output switch OSW1 are serially coupled between a bonding pad OPAD1 and the DAC 220, and the operational amplifier OP2 and the output switch OSW2 are serially coupled between the bonding pad OPAD2 and the DAC 230. When a test operation is initiated, the output switches OSW1 and OSW2 are turned on. By measuring the bonding pads OPAD1 and OPAD2 to determine whether the voltages thereon are maintained at the level of the first voltage VA1, the condition of the channels in the DACs 220 and 230 can be determined.

In order to differentiate the test operation with the normal operation of the source driver, the test circuit 200 of the source driver may further include a switch blocking module BSW1. The switch blocking module BSW1 is serially coupled between the DACs 220 and 230 and a gamma voltage generator 290. The switch blocking module BSW1 receives a test activating signal TEN, and according to the test activating signal TEN, the switch blocking module BSW1 breaks off or conducts the coupling between the gamma voltage generator 290 and the DACs 220 and 230. More specifically, when the test operation is activated, the switch blocking module BSW1 breaks off in accordance with the test activating signal TEN, so that the DACs 220 and 230 receive the first and second voltages VA1 and VA2 provided by the voltage selector 210. Conversely, when the test operation is terminated, the switch blocking module BSW1 is turned on in accordance with the test activating signal TEN, so that the DACs 220 and 230 receive a plurality of gamma voltages provided by the gamma voltage generator 290.

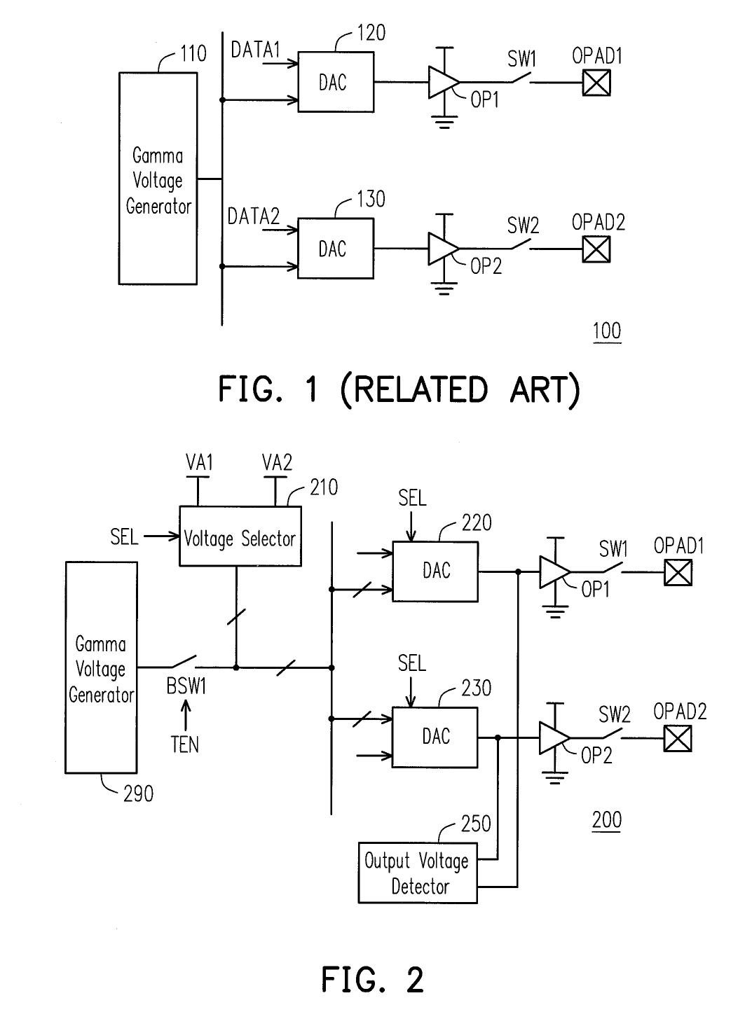

Compared to conventional technologies, the embodiment illustrated by FIG. 1 provides several advantages. For example, under the condition that the test results are detected through the bonding pads OPAD1 and OPAD2, when the test operation is activated, since the voltage values on the bonding pads OPAD1 and OPAD2 typically remain at the voltage level of the first voltage VA1, the operational amplifiers OP1 and OP2 do not need to continually modify the output voltage levels thereof. Therefore, a lengthy wait time during the test procedure is not required. Moreover, logic voltages may be employed for the first voltage VA1 and the second voltage VA2. Furthermore, the voltage level of the first voltage VA1 may be higher than the voltage level of the second voltage VA2. Since the voltage level of a logic voltage is relatively low, when the operational amplifiers OP1 and OP2 output the first voltage VA1, a long stabilizing time is not required, and thus a testing time can be drastically lowered.

In addition, it should be noted that, for a built-in self test (BIST) design of the source driver, the test circuit 200 of the source driver 200 may further include an output voltage detector 250. The output voltage detector 250 is coupled to the output terminals of the DACs 220 and 230, and is configured to detect whether the output terminals of the DACs 220 and 230 continuously output the first voltage VA1. This configuration has an advantage that testing of all the channels in the DACs 220 and 230 may be completed without routing through operational amplifiers, thereby further decreasing the testing time.

It should also be noted that a total of two DACs 220 and 230 in the present embodiment is used merely as an illustrative example, and not meant to place a limitation on the test circuit 200 of the source driver to a source driver having two DACs. In practice, the test circuit 200 of the source driver according to the present embodiment may be applied on a source driver having one or more DACs.

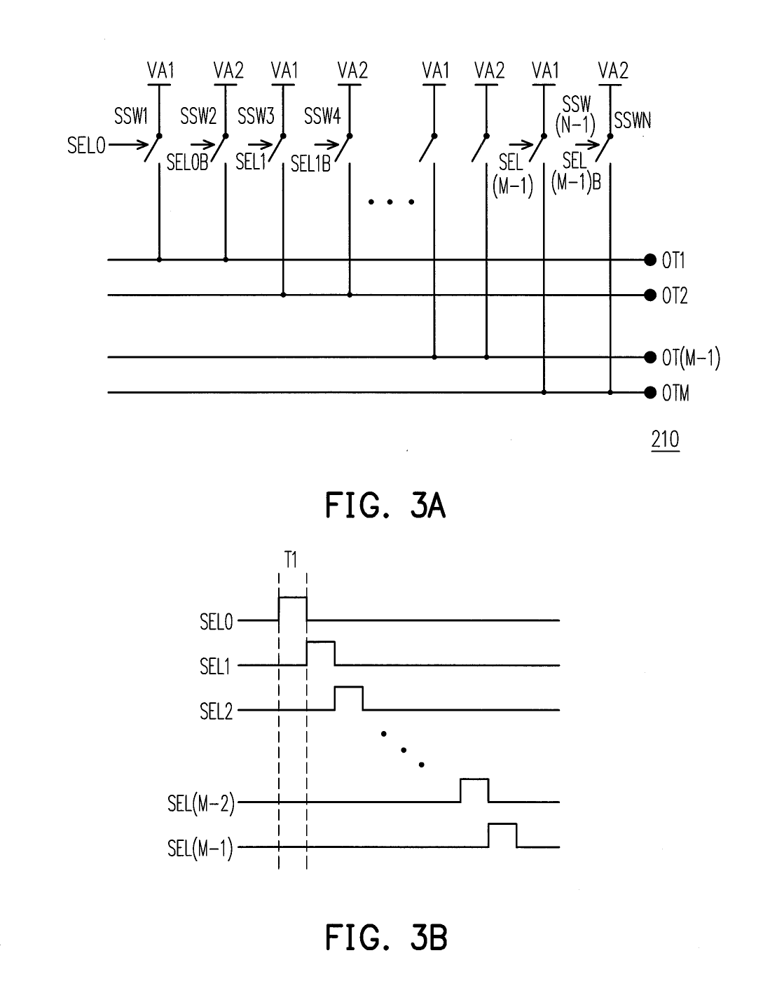

Referring to FIG. 3A, a schematic diagram of an implementation of the voltage selector 210 depicted in FIG. 2 according to an embodiment of the invention is shown. The voltage selector 210 includes a plurality of selection switches SSW1-SSWN. The selection switches SSW1, SSW3 . . . SSW(N−1) receive the first voltage VA1 and are respectively coupled to the output terminals OT1-OTM of the voltage selector 210, in which N=2×M and N and M are positive integers. Moreover, the selection switches SSW2, SSW4 . . . SSWN receive the second voltage VA2 and are also respectively coupled to the output terminals OT1-OTM of the voltage selector 210. Furthermore, the selection switches SSW1-SSWN sequentially receives a plurality of bits SEL0, SEL0B, SEL1, SEL1B . . . SEL(M−1), and SEL(M−1)B of the selection signal SEL, and the selection switches are turned on or off according to the plurality of bits SEL0, SEL0B, SEL1, SEL1B . . . SEL(M−1), and SEL(M−1)B of the selection signal SEL.

The bits SELx and SELxB of the selection signal SEL are opposite in polarity, in which x=0 . . . (M−1).

Referring to FIGS. 3A and 3B, a waveform diagram of the selection signal SEL in FIG. 2 according to an embodiment of the invention is shown in FIG. 3B. In a same time period, among the plurality of bits SEL0 . . . SEL(M−1) of the M-bits selection signal SEL, at most one of the bits is a logic high signal, with the rest of the bits being all logic low signals. Taking a time period T1 as an example, the first bit SEL0 of the selection signal SEL is the logic high signal, and the rest of the bits SEL1 . . . SEL(M−1) are all logic low signals. Referring to the schematic diagram illustrated in FIG. 3A, during the time period T1, only the output terminal OT1 outputs the first voltage VAL while the rest of the output terminals OT2-OTM output the second voltage VA2.

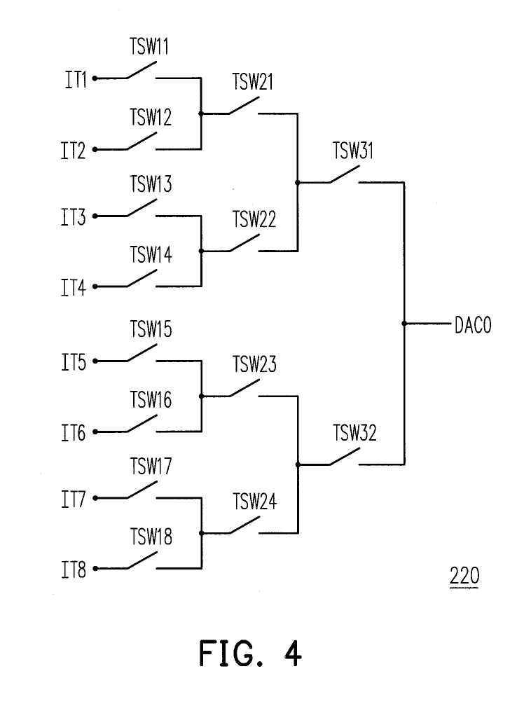

Referring to FIG. 4, a partial circuit diagram of the DAC 220 depicted in FIG. 2 according to an embodiment of the invention is shown. Taking an 8-bits DAC 220 as an example, the DAC 220 has eight input terminals IT1-IT8 and an output terminal DACO. A plurality of channels formed by a plurality of channel switches TSW11-TSW32 are disposed between the input terminals IT1-IT8 and the output terminal DACO. Briefly speaking, when the channel switches TSW11, TSW21, and TSW31 are turned on, the input terminal IT1 is coupled to the output terminal DACO through the channel formed by the channel switches TSW11, TSW21, and TSW31. When the channel switches TSW15, TSW23, and TSW32 are turned on, the input terminal ITS is coupled to the output terminal DACO through the channel formed by the channel switches TSW15, TSW23, and TSW32.

Preferably, only a single input terminal may be arranged to couple to the output terminal DACO. For example, when the input terminal T1 is coupled to the output terminal DACO through a channel, the rest of the input channels IT2-1T8 and the output terminal DACO are broken off.

The on or off states of the channel switches TSW11-TSW32 are coordinated with the output terminal which the voltage selector 210 outputs the first voltage VA1. In other words, when the input terminal IT1 of the DAC 220 is coupled to the output terminal of the voltage selector 210 outputting the first voltage VAL the channel switches TSW11, TSW21, and the TSW31 are correspondingly turned on, such that the first voltage VA1 received on the input terminal IT1 can be transmitted to the output terminal DACO of the DAC 220.

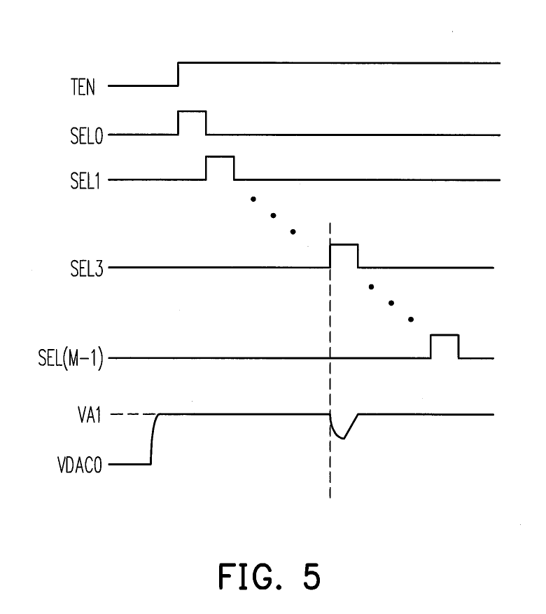

Referring to FIG. 5, an operational waveform diagram of the DAC 220 depicted in FIG. 4 according to an embodiment of the invention is shown. When the test operation is activated (i.e., the test activating signal TEN transitions from the low logic state to the high logic state), each of the bits SEL0 . . . SEL(M−1) of the selection signal SEL sequentially generates a positive pulse signal having a voltage value equal to the logic high signal. Correspondingly, under the condition that the channels of the DAC 220 are operating normally, the output terminal DACO of the DAC 220 may continuously output a voltage VDACO having a voltage value equal to the first voltage VA1. In the waveform diagram illustrated in FIG. 5, when the bit SEL3 of the selection signal SEL generates the positive pulse signal, the voltage VDACO on the output terminal DACO of the DAC 220 is no longer continuously equal to the first voltage VA1. Instead, the voltage VDACO is trending downwards, which represents a damaged channel in the DAC 220. It should be noted that, although the first voltage VA1 is taken to be greater than the second voltage VA2 as an example, in practice the invention is not limited thereto.

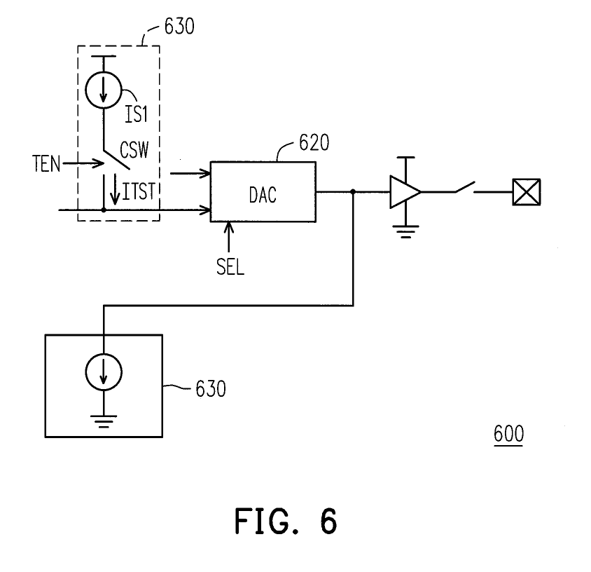

Referring to FIG. 6, a schematic diagram of a test circuit 600 of a source driver according to another embodiment of the invention is shown. The test circuit 600 of the source driver includes a test input current source 610, a DAC 620, and an output current detector 630. The test input current source 610 outputs a test input current ITST according to the test activating signal TEN. The DAC 620 is coupled to the test input current source 610 to receive the test input current ITST. The DAC 620 has a plurality of channels. According to the selection signal SEL, the DAC 620 transmits the test input current ITST at one of the channels in the DAC 620 in a sequential order to an output terminal of a DAC 612.

In the present embodiment, the test input current source 610 includes a current switch CSW and a current source IS1. The current switch CSW receives the test activating signal TEN and accordingly turns on or off. When the current switch CSW turns on according to the test activating signal TEN, the test input current ITST generated by the current source IS1 may be inputted to the DAC 620. Conversely, when the current switch CSW turns off according to the test activating signal TEN, the test input current ITST generated by the current source IS1 is prohibited from input to the DAC 620.

The output current detector 630 is coupled to the DAC 620 and is configured to receive and detecting a current value of the test input current ITST. In other words, when the current value of the current received by the output current detector 630 is not equal to the test input current ITST, then the channel in the DAC 620 transmitting the test input current ITST may be damaged.

After the DAC 620 sequentially conducts all of the channels transmitting the test input current ITST according to the selection signal SEL, the detection result of the output current detector 630 may determine whether the channels in the DAC 620 are damaged.

Using the configuration in the present embodiment, the testing of all the channels in the DAC 620 may be completed without routing through operational amplifiers, thereby drastically decreasing the testing time.

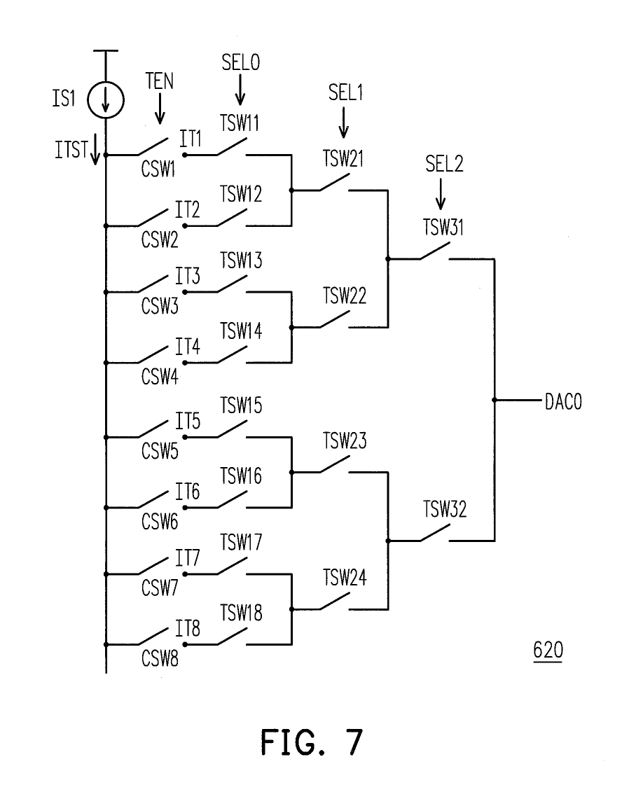

Referring to FIG. 7, a partial circuit diagram of the DAC 620 depicted in FIG. 6 according to an embodiment of the invention is shown. Taking an 8-bits DAC 620 as an example, the DAC 620 includes input terminals IT1-IT8 and channel switches TSW11-TSW32. Moreover, the channel switches TSW11-TSW32 receive the selection signal SEL and accordingly turn on or off. In the present embodiment, the selection signal SEL has three bits SEL0-SEL2. The bit SEL0 controls the on/off states of the channel switches TSW11-TSW18, the bit SEL1 controls the on/off states of the channel switches TSW21-TSW24, and the bit SEL2 controls the on/off states of the channel switches TSW31-TSW32.

When the test operation is activated, the current switches CSW1-CSW8 are turned on according to the test activating signal TEN. When the channel switches TSW11, TSW21, and TSW31 are all turned on, the test input current ITST is transmitted to the output terminal DACO of the DAC 620 through the current switch CSW1 and the channel switches TSW11, TSW21, and TSW31 from the input terminal IT1, and the test input current ITST flows through the output current detector 630. By changing the selection signal SEL, all of the channels in the DAC 620 can be conducted one by one for transmitting the test input current ITST, and accordingly complete the test operation.

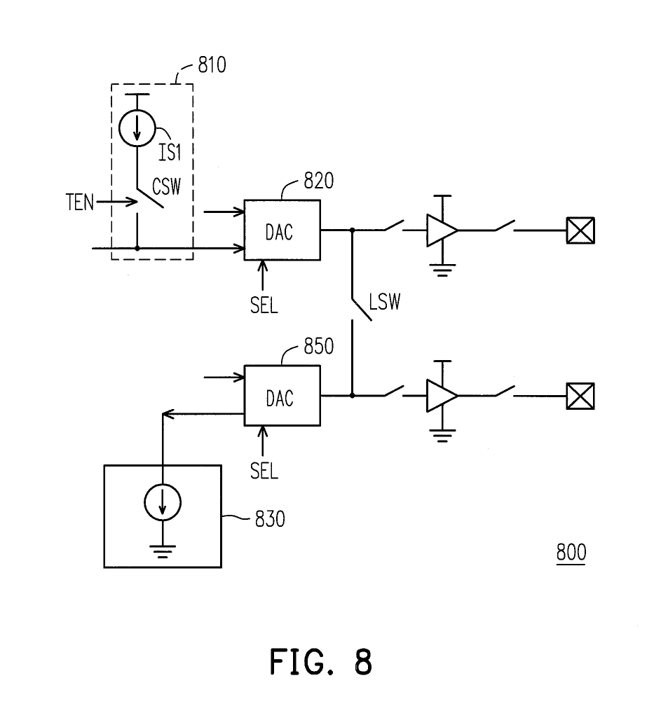

Referring to FIG. 8, a schematic diagram of a test circuit 800 of a source driver according to another embodiment of the invention is shown. The present embodiment is similar to the embodiment illustrated in FIG. 6, with a difference being that the test circuit 800 of the source driver in the present embodiment includes one or more DACs 820 and 850. When a test input current source 810 outputs the test input current ITST to the DAC 820 according to the test activating signal TEN, a connector switch LSW serially coupled between the output terminals of the DACs 820 and 850 also turns on in accordance with the test activating signal TEN. Therefore, the test input current ITST may be transmitted by the selected channel in DAC 820 to the output terminal of the DAC 820. Thereafter, the test input current ITST may be transmitted by the output terminal of the DAC 850 to the input terminal of the DAC 850, and then transmitted by the selected channel in the DAC 850 to the output terminal of the DAC 850. The test input current ITST is then transmitted to an output current detector 830 to detect the current value. Consequently, whether the channels in one or both of the DACs 820 and 850 are normal can be determined.

It should be noted that, during the test period, the DACs 820 and 850 may receive a selection signal SEL of different bit values for testing different combinations of channel switch conditions. Moreover, although the output current detectors 630 and 830 with built-in self test designs are used as examples, an alternative configuration may involve connections with bonding pads, and one or a plurality of switches may be turned on during the test period for detecting the test input current ITST at the bonding pads. Using the configuration in the afore-described embodiments, the testing of all the channels in the DAC 810 and 850 may be completed without routing through operational amplifiers, thereby drastically decreasing the testing time.

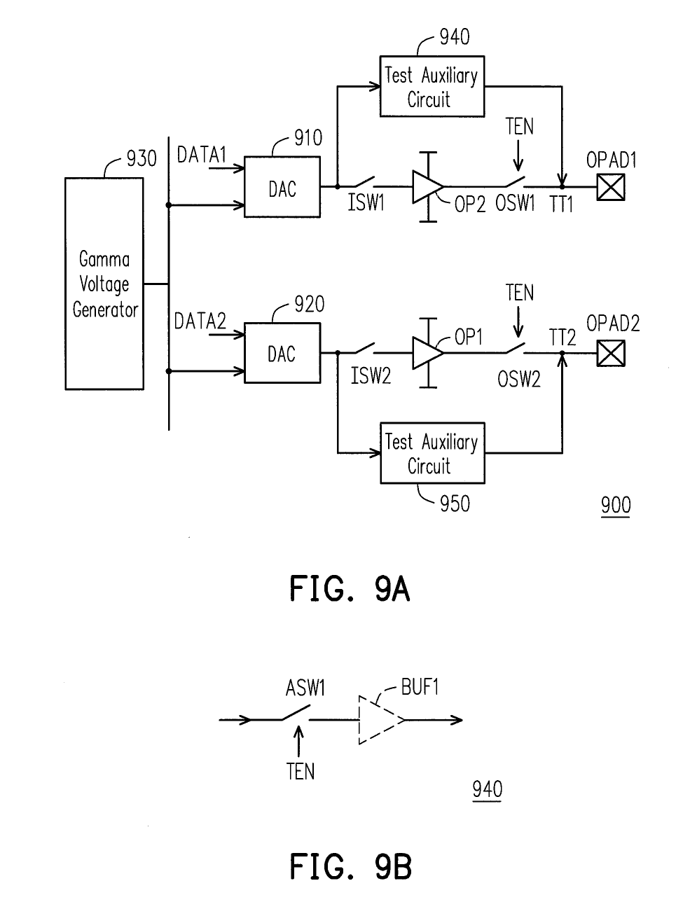

Referring to FIG. 9A, a schematic diagram of a test circuit 900 of a source driver according to another embodiment of the invention is shown. The test circuit 900 includes a gamma voltage generator 930, the DACs 910 and 920, the operational amplifiers OP1 and OP2, the output switches OSW1 and OSW2, and the test auxiliary circuits 940 and 950. The gamma voltage generator 930 is configured to generate a plurality of gamma voltages. The DACs 910 and 920 are respectively coupled to the gamma voltage generator 930. Moreover, the DACs 910 and 920 receive the display data DATA1 and DATA2 to select and output one of the gamma voltages generated by the gamma voltage generator 930.

The operational amplifiers OP1 and OP2 are respectively coupled to the DACs 910 and 920 and receive the outputs of the DACs 910 and 920. The output switches OSW1 and OSW2 are respectively coupled in series between the output terminals of the operational amplifiers OP1 and OP2 and the test terminals TT1 and TT2. The output terminals OSW1 and OSW2 receive the test activating signal TEN and accordingly turn on or off. More specifically, when the test operation is activated, the output switches OSW1 and OSW2 are turned off according to the test activating signal TEN. More specifically, when the test operation is completed, the output switches OSW1 and OSW2 are turned on according to the test activating signal TEN.

Moreover, the test terminals TT1 and TT2 may be respectively coupled directly to the bonding pads OPAD1 and OPAD2. When the test operation is activated, the voltage values on the test terminals TT1 and TT2 may be determined by measuring the voltages on the bonding pads OPAD1 and OPAD2. Alternatively, an extra output voltage detector (not shown) may be coupled to the test terminals TT1 and TT2, the extra output voltage detector configured to detect whether the output terminals of the 910 and 920 can output a stable voltage.

The test auxiliary circuits 940 and 950 are respectively coupled between the output terminals of the DACs 910 and 920 and the test terminals TT1 and TT2. The test auxiliary circuits 940 and 950 are configured to directly transmit the outputs of the DACs 910 and 920 to the test terminals TT1 and TT2 when the test activating signal TEN is enabled.

The test circuit 900 of the source driver further includes the input switches ISW1 and ISW2 respectively coupled in series between a coupling path of the DACs 910 and 920 and the operational amplifiers OP1 and OP2. The input switches ISW1 and ISW2 are turned on or off according to the test activating signal TEN. Moreover, the on/off states of the input switches ISW1 and ISW2 and the output switches OSW1 and OSW2 are the same.

Additionally, the DACs 910 and 920 in the present embodiment may be implemented by the structures described in FIG. 4 or 7, for testing each one of the plurality of channels in the DACs 910 and 920. A difference exists in that the voltages under test are generated by a gamma voltage generator 930. More specifically, the DACs 910 and 920 may also respectively include a plurality of input terminals and an output terminal, in which the input terminals are respectively coupled to the gamma voltage generator 930 to receive the outputted gamma voltages. In addition, the DACs 910 and 920 may also respectively include a plurality of channels coupled between the plurality of input terminals and the single output terminal. The DACs 910 and 920 may respectively output a gamma voltage to the output terminal through one of the channels in a sequential order.

Using the afore-described configuration, the testing of all the channels in the DACs 910 and 920 may be completed without routing through operational amplifiers, thereby drastically decreasing the testing time.

Referring to FIG. 9B, a schematic diagram of a test auxiliary circuit 940 depicted in FIG. 9A according to an embodiment of the invention is shown. The test auxiliary circuit 940 includes an auxiliary switch ASW1. The auxiliary switch ASW1 is serially coupled between the output terminal of the DAC 910 and the test terminal TT1. The auxiliary switch ASW1 receives the test activating signal TEN and accordingly turns on or off. Moreover, the on/off states of the output switches OSW1 and OSW2 and the auxiliary switch ASW1 and OSW2 are the complementary (i.e. opposite).

When the auxiliary switch ASW1 is turned on, in order for the voltage outputted by the output terminal of the DAC 910 to not weaken due to the transmission path provided by the test auxiliary circuit 940, the test auxiliary circuit 940 may further include an output buffer BUF1. The output buffer BUF1 is coupled between the auxiliary switch ASW1 and the test terminal TT1.

It should be noted that, in each of the afore-described embodiments, the plurality of input terminals of the DACs may all receive one or a plurality of test input signals. The test input signals are, for example, the first and second voltages VA1 and VA2 generated by the voltage selector 210 in FIG. 1, the test input current ITST generated by the test input current sources 610 and 810 in FIGS. 6 and 8, the test input current ITST outputted by the DAC 820 towards the DAC 850 in FIG. 8, and the gamma voltages generated by the gamma voltage generator 930 in FIG. 9A. Moreover, the DACs may switch the plurality of channels therein according to a selection signal, so as to output the received test signal by one of the input terminals as a test output signal at an output terminal in a sequential order. More importantly, the test output signal used to represent the test result passes through a test route which may be designed to include no operational amplifiers. For example, in different embodiments of the invention, the test routes may be provided by, for instance, the test auxiliary circuits having an auxiliary switch in FIGS. 9A and 9B, another DAC in FIG. 8, or the signal detector in FIG. 2 used for built-in self testing (e.g. the voltage detector or the current detector). Consequently, each of the embodiments can drastically decrease the testing time.

In view of the foregoing, according to the afore-described embodiments, by configuring extra transmission paths in the source driver to transmit current or voltage, the DACs in the source driver can be tested without relying directly on the operational amplifiers of the digital circuits during the test procedure. Accordingly, the testing speed can be drastically increased and the testing costs can be effectively lowered.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall

What is claimed is:

1. A test circuit of a source driver, comprising:
a voltage selector having a plurality of first output terminals, configured to output a first voltage at one of the first output terminals in a sequential order according to a selection signal and output a second voltage at the other first output terminals; and
at least one digital-to-analog converter (DAC), each of the at least one DAC having a plurality of the input terminals respectively coupled to the first output terminals, and having a second output terminal, configured to transmit the first voltage received by one of the input terminals to the second output terminal in a sequential order according to the selection signal.

2. The test circuit as claimed in claim 1, wherein a test result is determined according to whether a voltage of the second output terminal is stable at the first voltage during a time period the second output terminal is sequentially coupled to different first output terminals.

3. The test circuit as claimed in claim 1, wherein
each of the at least one DACs comprises a plurality of channels respectively coupled between the input terminals and the second output terminal, the channels conducting or breaking off according to the selection signal, for sequentially coupling the input terminal receiving the first voltage to the second output terminal.

4. The test circuit as claimed in claim 1, further comprising:
a switch blocking module serially coupled between the input terminals of the DAC and a gamma voltage generator, the switch blocking module breaking off or conducting according to a test activating signal.

5. The test circuit as claimed in claim 1, further comprising an output voltage detector coupled to the second output terminal, for detecting whether the second output terminal is continuously outputting the first voltage.

6. The test circuit as claimed in claim 5, further comprising:
an operational amplifier coupled between the output voltage detector and the second output terminal of the DAC; and
an output switch serially coupled between an output terminal of the operational amplifier and a bonding pad, the output switch receiving an output control signal and accordingly turning on or off.

7. A test circuit of a source driver, comprising:
a test input current source outputting a test input current at a first output terminal according to a test activating signal; and
a first DAC having a plurality of first input terminals coupled to the first output terminal, and a second output terminal, the first DAC configured to transmit the test input current received by one of the first input terminals to the second output terminal in a sequential order according to a selection signal, to serve as a first output current indicating a test result.

8. The test circuit as claimed in claim 7, further comprising an output current detector coupled to the second output terminal of the first DAC, for receiving and detecting a current value of the first output current.

9. The test circuit as claimed in claim 7, wherein the test result is determined according to whether the first output current is stable at the test input current during a time period the second output terminal is sequentially coupled to different first output terminals.

10. The test circuit as claimed in claim 7, wherein each of the at least one first DACs respectively has a plurality of first channels coupled between the input terminals and the second output terminal, the channels conducting or breaking off according to the selection signal, for sequentially coupling one of the first input terminals to the second output terminal.

11. The test circuit as claimed in claim 7, further comprising:
at least one second DAC, each of the at least one second DACs coupled to one of the corresponding first DACs, for generating a second output current indicating a test result according to the first output current outputted by the corresponding first DAC.

12. The test circuit as claimed in claim 11, wherein each of the at least one second DACs has a plurality of second input terminals coupled to one of the corresponding first DACs, and a third output terminal, the second DAC configured to transmit the first output current voltage received by one of the second input terminals to the third output terminal in a sequential order according to the selection signal, to serve as the second output current.

13. The test circuit as claimed in claim 11, further comprising an output current detector coupled to the third output terminal of the second DAC, for receiving and detecting a current value of the second output current.

14. The test circuit as claimed in claim 11, further comprising:
a connector switch serially coupled between the second output terminal of one of the at least one first DACs and the third terminal of the corresponding second DAC, the connector switch turning on or off according to a test activating signal.

15. The test circuit as claimed in claim 7, further comprising:
a switch blocking module serially coupled between the first DAC and a gamma voltage generator, the switch blocking module conducting or breaking off according to a test activating signal.

16. A test circuit of a source driver, comprising:
a gamma voltage generator for generating a plurality of gamma voltages;
at least one DAC, each of the DACs having a plurality of input terminals receiving one of the gamma voltages, and a second output terminal, for transmitting the gamma voltage received by one of the input terminals to the second output terminal in a sequential order according to the selection signal, to serve as an output voltage;
at least one operational amplifier, each of the at least one operational amplifiers coupled to the second output terminal of the corresponding DAC;
at least one output switch, each of the at least one output switches serially coupled between an output terminal of the corresponding operational amplifier and a corresponding one of at least one test terminals, the at least one output switches turning on or off according to a test activating signal; and
at least one test auxiliary circuit, each of the at least one test auxiliary circuits coupled between the second output terminal of the corresponding DAC and the corresponding test terminal, for transmitting the output voltage at the second output terminal of the corresponding DAC to the test terminal when the test activating signal is enabled.

17. The test circuit as claimed in claim 16, wherein a test result is determined according to whether the voltage at the test terminal is stable at the gamma voltage during a time period the second output terminal is sequentially coupled to different first output terminals.

18. The test circuit as claimed in claim 16, wherein each of the at least one DACs respectively has a plurality of channels coupled between the input terminals and the second output terminal, for sequentially coupling one of the input terminals to the second output terminal according to the selection signal determining whether the channels conducts or breaks off.

19. The test circuit as claimed in claim 16, wherein each of the at least one test auxiliary circuits comprises:
an auxiliary switch serially coupled between the second output terminal of the corresponding DAC and the corresponding test terminal, the auxiliary switch receiving the test activating signal and accordingly turning on or off.

20. The test circuit as claimed in claim 19, wherein each of the at least one test auxiliary circuits further comprises:
an output buffer coupled between the auxiliary switch and the test terminal.

21. The test circuit as claimed in claim 16, further comprising:
at least one input switch, each of the at least one input switches serially coupled between the corresponding DAC and the corresponding operational amplifier, and turning on or off according to the test activating signal.

22. A test circuit of a source driver, comprising:
an operational amplifier having an output terminal; and
a DAC having a plurality of input terminals coupled to one or more test input signals, and an output terminal coupled to the input terminal of the operational amplifier, the DAC configured to transmit the test signal received by one of the input terminals to the output terminal in a sequential order according to a selection signal to serve as a test output signal,
wherein the test output signal is outputted from the test circuit through a test path to indicate a test result, the test path not passing through the operational amplifier.

23. The test circuit as claimed in claim 22, wherein the test circuit further comprises one of a test auxiliary circuit having an auxiliary switch, another DAC, and a signal detector for a built-in self test, respectively configured to provide the test path.

24. The test circuit as claimed in claim 22, wherein the test circuit further comprises one of a voltage selector for outputting a first voltage at one of a plurality of output terminals in a sequential order and outputting a second voltage at the other output terminals, a gamma voltage generator, another DAC, and a test input current source, respectively configured to provide the one or more test input signals.
